(19) United States
(12) Patent Application Publication
(10) Pub. No.: US 2024/0006176 A1
(43) Pub. Date: Jan. 4, 2024

(54) METHOD OF FORMING P-TYPE DOPED SILICON-GERMANIUM LAYERS AND SYSTEM FOR FORMING SAME

(71) Applicant: ASM IP Holding B.V., Almere (NL)

(72) Inventors: Lucas Petersen Barbosa Lima, Heverlee (BE); Charles Dezelah, Helsinki (FI); Rami Khazaka, Leuven (BE); Qi Xie, Shanghai (CN); Giuseppe Alessio Verni, Jodoigne (BE)

(21) Appl. No.: 18/214,656

(22) Filed: Jun. 27, 2023

Related U.S. Application Data
(60) Provisional application No. 63/356,634, filed on Jun. 29, 2022.

(51) Int. Cl. H01L 21/02; C30B 29/52; C30B 25/02

(52) U.S. Cl. CPC H01L 21/0262; H01L 21/02532; C30B 25/02; C30B 29/52; H01L 21/02579

(57) ABSTRACT

Methods and systems for forming a p-type doped silicon germanium layer. The p-type doped silicon germanium layer can include silicon, germanium, gallium, and, in at least some cases, indium.

### CROSS-REFERENCE TO RELATED APPLICATIONS

This application is a nonprovisional of, and claims priority to and the benefit of, U.S. Provisional Patent Application No. 63/356,634, filed Jun. 29, 2022 and entitled “METHOD OF FORMING P-TYPE DOPED SILICON-GERMANIUM LAYERS AND SYSTEM FOR FORMING SAME,” which is hereby incorporated by reference herein.

### FIELD OF THE INVENTION

The present disclosure generally relates to methods and systems suitable for forming electronic devices. More particularly, the disclosure relates to methods and systems that can be used for forming doped semiconductor material on a surface of a substrate.

### BACKGROUND OF THE DISCLOSURE

The scaling of semiconductor devices, such as, for example, complementary metal-oxide-semiconductor (CMOS) devices, has led to significant improvements in speed and density of integrated circuits. However, conventional device scaling techniques face significant challenges for future technology nodes.

One approach to improve semiconductor device performance is to enhance the carrier mobility, and consequently the transistor drive current, utilizing strain induced effects. For example, it has been shown that the hole mobility may be considerably enhanced in p-channel Group IV semiconductor transistors employing stressor regions, such as stressor regions employed in the source and drain regions of the transistors.

Further, reduction in contact resistance to the active regions of a semiconductor device structure may be desirable for ongoing device improvement at future technology nodes. For example, for (e.g., complimentary) metal-oxide-semiconductor (CMOS) device structures, a contact resistance may include the electrical resistance between a contact structure and one or more active (e.g., stressor) regions, such as source and drain regions of the device structure. In the case of an n-type MOS device, the stressor region may comprise a highly doped region, i.e., with a carrier density of approximately 5×1020 cm⁻³ or more, doped with either phosphorus or arsenic. The high doping levels that may be achieved in the n-type MOS device stressor region may result in a contact resistivity below 0.3 mΩ-cm. However, for a p-type MOS device, boron is typically used as a dopant. In some cases, boron may have relatively low solubility in the semiconductor material, and thus high concentrations of the p-type dopant and thus low contact resistance to the semiconductor material can be difficult to obtain.

By way of examples, attempts to lower the contact resistance of silicon germanium films include growing SiGe layers with high boron concentrations. However, high boron concentrations are difficult to achieve with higher Ge:Si ratios due to the low boron solubility in germanium, and therefore, attempts to simply increase the boron concentration in the silicon germanium film have generally not been sufficient to decrease the contact resistivity of the silicon germanium layers to desired values.

Further attempts to decrease the contact resistance to the silicon germanium and similar films include the addition of another dopant, in which the first dopant (e.g., boron) may be soluble, and a high-temperature anneal process. Such techniques may be problematic because the use of the relatively high temperatures during the anneal process can lead to clustering of one or more of the dopants at a surface of the doped semiconductor films.

Furthermore, in some applications, it may be desirable to selectively deposit semiconductor material (e.g., highly-doped Group IV semiconductor material). However, such techniques may heretofore not be well developed.

Accordingly, improved methods and systems for depositing doped semiconductor material are desired. Structures and devices formed using the methods and/or systems are also desired.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY OF THE DISCLOSURE

Various embodiments of the present disclosure relate to methods of forming structures, to structures and devices formed using such methods, and to apparatus for performing the methods and/or for forming the structures and/or devices. While the ways in which various embodiments of the present disclosure address drawbacks of prior methods and systems are discussed in more detail below, in general, various embodiments of the disclosure provide improved methods of forming doped semiconductor layers that exhibit relatively low contact resistance. Additionally or alternatively, the doped semiconductor layers can be formed at relatively low temperatures. Further, exemplary doped semiconductor layers can be selectively formed overlying a first portion of a substrate surface relative to a second portion of the substrate surface.

In accordance with embodiments of the disclosure, a method of forming a p-type doped silicon germanium layer is provided. An exemplary method includes providing a substrate within a reaction chamber of a reactor and forming the p-type doped silicon germanium layer by providing a silicon precursor to the reaction chamber, providing a germanium precursor to the reaction chamber, and providing one or more p-type dopant precursors to the reaction chamber, wherein the one or more p-type dopant precursors comprise boron, gallium and indium. In accordance with examples of these embodiments, the p-type doped silicon germanium layer is epitaxially formed on the substrate. In accordance with further examples, the one or more p-type dopant precursors can include two or more of boron, gallium and indium. By way of examples, the one or more p-type dopant precursors comprise one or more of a borane having a formula BₓH_{y} where x is between 1-12 and where y≥x and y≤3x. (common examples include BH₃, B₂H₆, B₄H₁₀, B₅H₉, and B₁₀H1₄; deuterium-diborane (B₂D6); boron halides (e.g., BF₃, BCl₃, BBr₃, and BI₃); triethylboron; or one or more borohydride compounds. The one or more borohydride compounds can comprise a borohydride represented by the formula YₓM(BH₄)₃₋ₓ, wherein Y is independently chosen from hydrogen, deuterium, chlorine, bromine, and iodine; M is a Group 13 metal independently chosen from gallium and indium; and x is an integer from 0-2. In accordance with other examples, the one or more borohydride compounds comprise a borohydride represented by the formula RₓM(BH₄)₃₋ₓ, wherein R is independently chosen from CH₃, C₂H₅, C₆H₅, CF₃SO₃, and NH₂; M is a Group 13 metal independently chosen from gallium and indium; and x is an integer from 1 to 3. In accordance with further examples, the one or more p-type dopant precursors comprise one or more of an indium organometallic compound and an indium halide compound.

In accordance with additional embodiments of the disclosure, a method of forming a p-type doped silicon germanium layer includes providing a substrate within a reaction chamber of a reactor and forming the p-type doped silicon germanium layer comprising boron and gallium by providing a silicon precursor to the reaction chamber, providing a germanium precursor to the reaction chamber, and providing one or more p-type dopant precursors to the reaction chamber, wherein the one or more p-type dopant precursors comprise one or more of gallium tribromide or gallium triiodide.

In accordance with yet further examples of the disclosure, a method of forming a p-type doped silicon germanium layer includes providing a substrate within a reaction chamber of a reactor and forming the p-type doped silicon germanium layer, the step of forming comprising: providing a silicon precursor to the reaction chamber, providing a germanium precursor to the reaction chamber, and providing one or more p-type dopant precursors to the reaction chamber, wherein the silicon precursor comprises one or more of bromine and iodine. The silicon precursor can be represented by the formula SiXₐH₄₋ₐ, wherein each X is an independently selected halogen selected from the group consisting of I and Br; and a is at least 1 and not more than 4.

In accordance with further examples of the disclosure, a structure comprises a substrate and p-type doped silicon germanium layer formed according to a method described herein.

In accordance with yet additional examples, a system for performing a method as described herein is provided.

These and other embodiments will become readily apparent to those skilled in the art from the following detailed description of certain embodiments having reference to the attached figures. The invention is not being limited to any particular embodiments disclosed.

### BRIEF DESCRIPTION OF THE DRAWING FIGURES

A more complete understanding of the embodiments of the present disclosure may be derived by referring to the detailed description and claims when considered in connection with the following illustrative figures.

FIG. 1 illustrates a method in accordance with exemplary embodiments of the disclosure.

FIG. 2 illustrates a method in accordance with another exemplary embodiment of the disclosure.

FIG. 3 illustrates a method in accordance with yet another exemplary embodiment of the disclosure.

FIG. 4 illustrates a structure in accordance with examples of the disclosure.

FIG. 5 illustrates a reactor system in accordance with additional exemplary embodiments of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

The description of exemplary embodiments of methods, structures, devices and systems provided below is merely exemplary and is intended for purposes of illustration only; the following description is not intended to limit the scope of the disclosure or the claims. Moreover, recitation of multiple embodiments having stated features is not intended to exclude other embodiments having additional features or other embodiments incorporating different combinations of the stated features. For example, various embodiments are set forth as exemplary embodiments and may be recited in the dependent claims. Unless otherwise noted, the exemplary embodiments or components thereof may be combined or may be applied separate from each other.

As set forth in more detail below, various embodiments of the disclosure provide methods of forming p-type doped silicon germanium layers. Exemplary methods can be used to, for example, form source and/or drain regions of semiconductor devices that exhibit relatively high mobility, relatively low contact resistance, and that maintain the structure and composition of the deposited layers. By way of examples, the layers can be used as p-type doped source and/or drain regions in MOSFETs. Exemplary MOSFETs in which these layers can be used include FinFETs and GAA (Gate-All-Around) FETs. In addition, the present layers are especially useful for the formation of shallow junctions because of a reduced channeling effect. In some embodiments, the present methods involve selectively depositing p-type doped silicon germanium layers overlying a first surface of the substrate, relative to a second surface of the substrate.

In this disclosure, “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, a multi-port injection system, other gas distribution device, or the like, can be used for, e.g., sealing the reaction space, and can include a seal gas, such as a noble gas. In some cases, the term “precursor” can refer to a compound that participates in the chemical reaction that produces another compound, and particularly to a compound that constitutes a film matrix or a main skeleton of a film; the term “reactant” can be used interchangeably with the term precursor. The term “inert gas” can refer to a gas that does not take part in a chemical reaction and/or does not become a part of a film matrix to an appreciable extent. Exemplary inert gases include He, Ar, N₂, and any combination thereof.

As used herein, the term “substrate” can refer to any underlying material or materials that can be used to form, or upon which, a device, a circuit, or a film can be formed. A substrate can include a bulk material, such as silicon (e.g., single-crystal silicon), other Group IV materials, such as germanium, or other semiconductor materials, such as a Group II-VI or Group III-V semiconductor, and can include one or more layers overlying or underlying the bulk material. Further, the substrate can include various features, such as recesses, protrusions, and the like formed within or on at least a portion of a layer of the substrate. As set forth in more detail below, a surface of a substrate can include two or more areas, wherein each of the two or more areas comprise different material and/or material with different crystalline structure.

As used herein, the term “epitaxial layer” can refer to a substantially single crystalline layer upon an underlying substantially single crystalline substrate or layer.

As used herein, the term “chemical vapor deposition” can refer to any process wherein a substrate is exposed to one or more volatile precursors, which react and/or decompose on a substrate surface to produce a desired deposition.

As used herein, the term “silicon germanium” can refer to a semiconductor material comprising silicon and/or germanium and can be represented as Si₁₋ₓGeₓ wherein 1≥x≥0, or 0.2≥x≥0.8, or 0.4≥x≥0.6, or materials comprising silicon and germanium having compositions as set forth herein.

As used herein, the term “film” and/or “layer” can refer to any continuous or non-continuous structures and material, such as material deposited by the methods disclosed herein. For example, film and/or layer can include two-dimensional materials, three-dimensional materials, nanoparticles or even partial or full molecular layers or partial or full atomic layers or clusters of atoms and/or molecules. A film or layer may comprise material or a layer with pinholes, which may be at least partially continuous. Alternatively, a film or layer may consist entirely of isolated islands.

As used herein, the term “monocrystalline” may refer to a material that includes a substantial single crystal, i.e., a crystalline material that displays long range ordering. It should, however, be appreciated that a “monocrystalline” material may not be a perfect single crystal but may comprise various defects, stacking faults, atomic substitutions, and the like, as long as the “monocrystalline” material exhibits long range ordering.

As used herein, the term “non-monocrystalline” may refer to a material that does not comprise a substantial single crystal, i.e., a material which displays either short range ordering or no ordering of the crystalline structure. Non-monocrystalline materials may comprise polycrystalline materials which may display short range ordering and amorphous materials which may display substantially no ordering of the crystalline structure.

As used herein, a “structure” can include a substrate as described herein. Structures can include one or more layers overlying the substrate, such as one or more layers formed according to a method as described herein.

Further, in this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like. Further, in this disclosure, the terms “including,” “constituted by” and “having” refer independently to “typically or broadly comprising,” “comprising,” “consisting essentially of,” or “consisting of” in some embodiments. It shall be understood that when a composition, method, device, etc. is said to comprise certain features, it means that it includes those features, and that it does not necessarily exclude the presence of other features, as long as they do not render the claim unworkable. This notwithstanding, the wording “comprises” or “includes” includes the meaning of “consists of,” i.e., the case when the composition, method, device, etc. in question only includes the features, components, and/or steps that are listed, and does not contain any other features, components, steps, and the like, and includes “consisting essentially of.”

In this disclosure, any defined meanings do not necessarily exclude ordinary and customary meanings in some embodiments.

The term “carrier gas” as used herein may refer to a gas that is provided to a reactor chamber together with one or more precursors. For example, a carrier gas may be provided to the reactor chamber together with one or more of the precursors used herein. Exemplary carrier gases include N₂, H₂, and noble gases such as He, Ne, Kr, Ar, and Xe.

Examples of the disclosure relate to (e.g., epitaxial) deposition p-type doped silicon germanium layers. The presently disclosed methods and devices allow for deposition of p-type doped silicon germanium layers with low resistance, at low temperatures, and other desirable properties. The layers may be used, for example, as a p-type doped source and/or drain regions in field effect transistors, and may be particularly well suited for use as a p-type doped source and/or drain regions in FinFET or gate-all-around device structures.

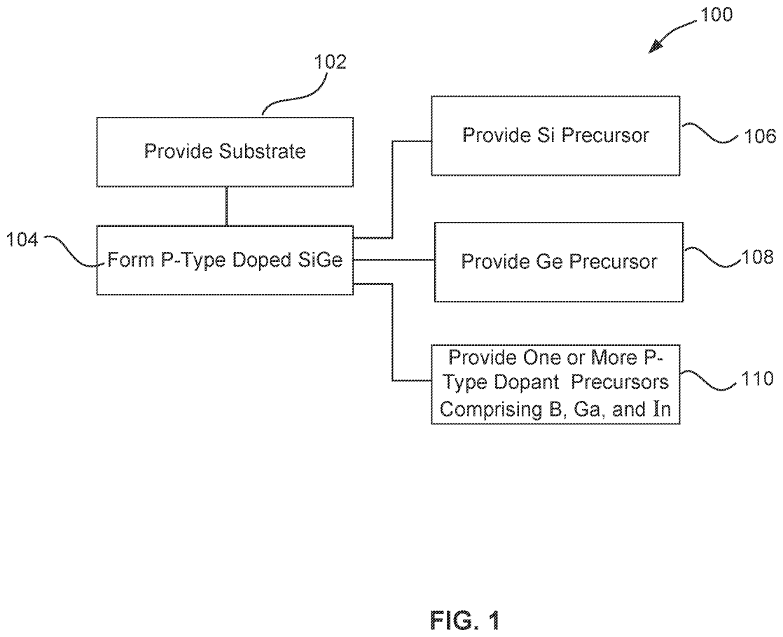

Turning now to the figures, FIG. 1 illustrates a method 100 in accordance with exemplary embodiments of the disclosure. Method 100 includes the steps of providing a substrate 102 and forming a p-type doped silicon germanium layer 104.

Step 102 includes providing a substrate within a reaction chamber of a reactor. The substrate can include any substrate as described herein. As a non-limiting example, the reaction chamber used during step 102 can comprise a reaction chamber of a chemical vapor deposition system. However, it is also contemplated that other reaction chambers and alternative chemical vapor deposition systems may also be utilized to perform the embodiments of the present disclosure. The reaction chamber can be a stand-alone reaction chamber or part of a cluster tool. By way of example, the substrate can include monocrystalline (e.g., Group 14) semiconductor material and a surface comprising such material.

During step 102, a reaction chamber can be brought to a desired temperature and pressure. For example, step 102 can include heating the substrate to a desired deposition temperature within the reaction chamber. In some embodiments of the disclosure, step 102 includes heating the substrate to a temperature of less than approximately 1100° C., or to a temperature of less than approximately 800° C., or to a temperature of less than approximately 650° C., or to a temperature of less than approximately 600° C., or to a temperature of less than approximately 550° C., or to a temperature of less than approximately 500° C., or to a temperature of less than approximately 450° C. For example, in some embodiments of the disclosure, heating the substrate to a deposition temperature may comprise heating the substrate to a temperature between approximately 400° C. and approximately 1100° C. or approximately 400° C. and approximately 800° C. or between about 300° C. and about 800° C. or between about 350° C. and about 500° C.

In addition to controlling the temperature of the substrate, a pressure within the reaction chamber may also be regulated. For example, in some embodiments of the disclosure, the pressure within the reaction chamber during method 100 may be less than 760 Torr, or less than 350 Torr, or less than 100 Torr, or less than 50 Torr, or less than 25 Torr, or even less than 10 Torr. In some embodiments, the pressure in the reaction chamber may be between 10 Torr and 760 Torr, between 10 Torr and 200 Torr, between 10 Torr and 100 Torr, or between 10 Torr and 80 Torr.

During step 104, a silicon precursor is provided to the reaction chamber (substep 106), a germanium precursor is provided to the reaction chamber (substep 108), and one or more p-type dopant precursors are provided to the reaction chamber (substep 110). Although separately illustrated, substeps 106-110 can overlap in time, such that the silicon precursor, the germanium precursor, and the and one or more p-type dopant precursors are all provided to the reaction chamber for a period of time. The precursors can be provided to the reaction chamber through one or more gas injectors, such as multi-port injectors (MPIs) including a plurality of individual port injectors for providing a gas mixture into the reaction chamber. Various combinations of the precursors can be supplied to one or more of the individual port injectors to fine tune concentration profiles as desired. A temperature and pressure within the reaction chamber during step 104 can be as described above in connection with step 102.

Exemplary silicon precursors suitable for substep 106 include one or more of a silane, an alkylsilane, and a halogen-substituted silane. In some cases, the silicon precursor does not include a halogen-substituted silane. Particular examples of suitable silicon precursors include silane (SiH₄), disilane (Si₂H₆), trisilane (Si₃H₈), tetrasilane (Si₄H₁₀), pentasilane (Si₅H₁₂), neopentasilane (Si₅H₁₂) and cyclohexasilane (Si₆H₁₂), methylsilane (CH₃—SiH₃), hexachlorodisilane (Si₂Cl₆), pentachlorodisilane (HSi₂Cl₅), octachlorotrisilane (Si₃Cl₈), dichlorosilane (H₂SiCl₂), diiodosilane (H₂SiI₂) and other suitable silicon-containing precursors.

Exemplary germanium precursors suitable for substep 108 include at least one of germane (GeH₄), digermane (Ge₂H₆), trigermane (Ge₃H₈), or germylsilane (GeH₆Si), or other suitable germanium-containing precursors. In some cases, the germanium precursor can include a halogen substituted germanium compound, e.g. GeCl₄, GeHCl₃, GeH₂Cl₂, and the like.

Substep 110 includes providing one or more p-type dopant precursors to the reaction chamber, wherein the one or more p-type dopant precursors comprise boron, gallium and indium. In some cases, a p-type dopant precursor can include two or more of boron, gallium and indium, such that less than three precursors can be provided during this substep.

In accordance with examples of the disclosure, the one or more p-type dopant precursors comprise one or more of a borane having a formula BₓH_{y} where x is between 1-12 and where y≥x and y≤3x. (common examples include BH₃, B₂H₆, B₄H₁₀, B₅H₉, and B₁₀H₁₄. diborane (B₂H₆); deuterium-diborane (B₂D₆); boron halides (e.g., BF₃, BCl₃, BBr₃, and BI₃); triethylboron; or one or more borohydride compounds. In accordance with examples of the disclosure, the one or more borohydride compounds can comprise a borohydride represented by the formula YₓM(BH₄)₃₋ₓ, wherein Y is independently chosen from hydrogen, deuterium, chlorine, bromine, and iodine; M is a Group 13 metal independently chosen from gallium and indium; and x is an integer from 0-2. In accordance with additional examples of the disclosure, the one or more borohydride compounds are selected from the group consisting of gallium borohydride (Ga(BH₄)₃) and indium borohydride (In(BH₄)₃). In accordance with other examples, the one or more borohydride compounds comprise a borohydride represented by the formula RₓM(BH₄)₃₋ₓ, wherein R is independently chosen from CH₃, C₂H₅, C₆H₅, CF₃SO₃, and NH₂; M is a Group 13 metal independently chosen from gallium and indium; and x is an integer from 1 to 3.

In accordance with further examples, the one or more p-type dopant precursors can include one or more of an indium organometallic compound and an indium halide compound. Exemplary organometallic compounds include one or more of an indium (e.g., C1-C6) alkyl compound and an indium (e.g., C1-C6) alkyl-amino compound. By way of particular examples, the one or more p-type dopant precursors comprise one or more of trimethylindium, triethylindium, and dimethylaminopropyl-dimethyl-indium. Exemplary indium halide compounds include indium trichloride. In accordance with additional examples, the one or more p-type dopant precursors can include indium and one or more of one or more adducts selected from the group BH₃—NR₃, BH₃—SR₂, and B(NR₂)₃, wherein each R can be independently selected from hydrogen, methyl, ethyl, 1-propyl, 2-propyl, cyclopropyl, 1-butyl, 2-butyl, 2-methylpropyl, tert-butyl, cyclobutyl, 1-pentyl, 1,1-dimethylpropyl, 2,2-dimethylpropyl, 3-methylbutyl, 1-methylbutyl, 1-ethylpropyl, 1,2-dimethylpropyl, 2-methylbutyl, cyclopentyl, 1-hexyl, 2-hexyl, 3-hexyl, 1-methyl-1-ethylpropyl, 1,1-dimethylbutyl, cyclohexyl, phenyl, benzyl, trimethylsilyl, and triethylsilyl functional groups.

The one or more p-type dopant precursors can be provided to the reaction chamber with a carrier gas. In such cases, a (e.g., volumetric flow) ratio of the carrier gas to the one or more p-type dopant precursors can be between about 50 and about 1000 or about 100 and about 500. In some cases, a volumetric flow ratio of an indium precursor to a boron precursor can be between about 0.1 and about 0.3. In some cases, a volumetric flow ratio of an indium precursor to a gallium precursor can be between about 0.1 and about 10. In some cases, a volumetric flow ratio of a gallium precursor to a boron precursor can be between about 0.1 and about 30.

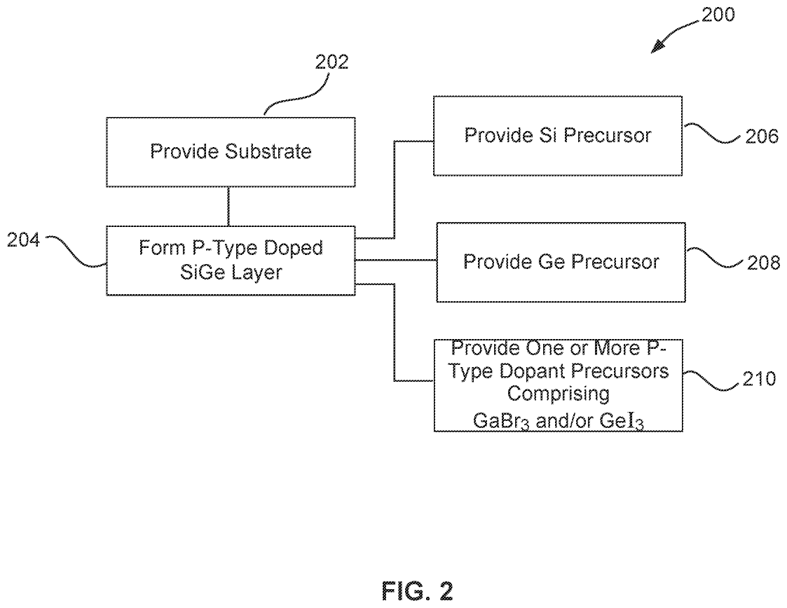

FIG. 2 illustrates another method 200 in accordance with exemplary embodiments of the disclosure. Similar to method 100, method 200 includes the steps of providing a substrate 202 and forming a p-type doped silicon germanium layer 204. In accordance with examples of the disclosure, the p-type doped silicon germanium layer can include boron and gallium and optionally indium.

Step 202 can be the same or similar to step 102 as described above. In some cases, a temperature of the substrate during step 202 and/or 204 can be less than 500° C., less than 450° C., or between about 300° C. and about 400° C. or between about 320° C. and about 380° C.

During step 204, a silicon precursor is provided to the reaction chamber (substep 206), a germanium precursor is provided to the reaction chamber (substep 208), and one or more p-type dopant precursors are provided to the reaction chamber (substep 210). Substeps 206 and 208 can be the same or similar to substeps 106, 108 described above.

During substep 210, one or more p-type dopant precursors are provided to the reaction chamber, wherein the one or more p-type dopant precursors comprise one or more of gallium tribromide or gallium triiodide. Substep 210 can be the same or similar to substep 110 described above, except that at least one of the one or more p-type dopant precursors comprise one or more of gallium tribromide or gallium triiodide. Use of gallium tribromide and/or gallium triiodide precursors can reduce an amount of carbon in a p-type doped silicon germanium layer that might otherwise exist. The reduction in carbon is thought to further reduce a contact resistance, reduce impurities on the a p-type doped silicon germanium layer, improve (e.g., source and/or drain) resistance, and avoid strain loss (C is a small atom) in the p-type doped silicon germanium layer, each of which are generally desirable properties for the next technology nodes. Further, unlike chlorinated gallium precursors, the precursors of this embodiment do not negatively affect gallium incorporation into the p-type doped silicon germanium layer. For example, the contact resistivity of the p-type doped silicon germanium layer can be further reduced to values lower than 10⁻¹⁰Ω·cm² without annealing.

In accordance with further examples of method 200, each of the silicon precursor, the germanium precursor and the one or more p-type dopant precursors can be selected (e.g., from those precursors noted above) that are chlorine-free.

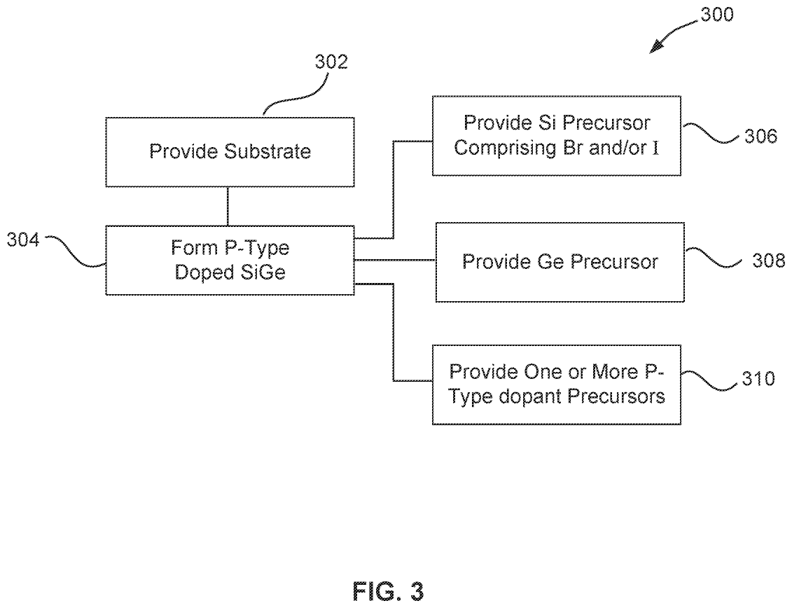

FIG. 3 illustrates another method 300 in accordance with exemplary embodiments of the disclosure. Similar to method 100 and method 200, method 300 includes the steps of providing a substrate 302 and forming a p-type doped silicon germanium layer 304. In accordance with examples of the disclosure, the p-type doped silicon germanium layer can include boron and gallium and optionally indium.

Step 302 can be the same or similar to steps 102, 202 as described above.

During step 304, a silicon precursor comprising one or more of bromine and iodine is provided to the reaction chamber (substep 306), a germanium precursor is provided to the reaction chamber (substep 308), and one or more p-type dopant precursors are provided to the reaction chamber (substep 310). Substeps 308 and 310 can be the same or similar to substeps 108, 110 described above.

During substep 310, a silicon precursor comprising one or more of bromine and iodine is provided to the reaction chamber. An advantage of using such precursors is that a substrate temperature during step 304 can be relatively low—e.g., less than 500° C., less than 450° C., or between about 300° C. and about 400° C. or between about 320° C. and about 380° C. In some cases, to obtain desired gallium concentrations, in accordance with examples of the disclosure, method 300 does not include use of a chlorine-containing precursor.

In accordance with these examples, the silicon precursor can be represented by the formula SiXₐH₄₋ₐ, wherein each X is an independently selected halogen selected from the group consisting of I and Br; and a is at least 1 and not more than 4. By way of particular examples, the silicon precursor can be or include diiodosilane (SiI₂H₂). In accordance with further examples, the silicon precursor can include two or more silicon atoms and can be represented by the formula SiₐX2ₐ₊₂₋ₙHₙ, where a is from 2 to 5. Alternatively, if the compound is cyclic, then the formula could be SiₐX2ₐ₋ₙHₙ, where a is 3-6.

In accordance with further examples of the disclosure, one or more of methods 100-300 can be used to selectively deposit a p-type doped silicon germanium layer (e.g., on a first surface (e.g., comprising silicon or silicon germanium) relative to a second surface (e.g., silicon oxide, nitride, or oxynitride)). For example, a selectivity can be greater than 10 or between 2 and 5.

In some embodiments, the silicon precursor, the germanium precursor, the boron precursor, and the gallium precursor are substantially free of chlorine. In some embodiments, all such precursors used do not contain chlorine. In some embodiments, none of the precursors contain chlorine.

It shall be understood that a method as described herein may be carried out after any suitable pre-clean. One possible pre-clean is a plasma clean that results in an H-terminated silicon surface. Another possible pre-clean uses wet chemistry. For example, the following sequence may be used: surface oxidation in a mixture consisting of NH₄OH, H₂O₂, and H2O; followed by a rinse; followed by an HF dip; followed by a rinse. A suitable HF dip comprises, for example, a dip in a mixture consisting of at least 0.1 vol. % to at most 1.5 vol. % HF in water. Additionally or alternatively, a gas-phase pre-dean may be used.

As noted above, in some cases, a carrier gas can be used to provide one or more precursors to the reaction chamber. In some embodiments, the carrier gas is provided to the reactor chamber at a flow rate from at least 100 sccm to at most 30000 sccm, or from at least 200 sccm to at most 20000 sccm, or from at least 300 sccm to at most 10000 sccm, or from at least 500 sccm to at most 5000 sccm, or from at least 750 sccm to at most 2500 sccm, or from at least 10000 sccm to at most 20000 sccm, or of 15000 sccm.

In some embodiments, the silicon precursor is SiH₄. SiH₄ may be provided to the reactor chamber as 100% SiH₄. Alternatively, SiH₄ may be diluted, e.g., in H₂, e.g., as from at least 1.0 to at most 2.0 vol. %, from at least 2.0 vol. % to at most 5.0 vol. %, from at least 5.0 vol. % to at most 10.0 vol. %, from at least 10.0 vol. % to at most 20.0 vol. %, from at least 20.0 vol. % to at most 50.0 vol. %, or from at least 50.0 vol. % to at most 99.9 vol. % SiH₄ in H₂.

In some embodiments, the germanium precursor is GeH₄. GeH₄ may be provided to the reactor chamber as 100% GeH₄. Alternatively, GeH₄ may be diluted, e.g., in H₂. E.g., GeH₄ in H₂ may be provided in a concentration from at least 1.0 vol. % to at most 2.0 vol. %, from at least 2.0 vol. % to at most 5.0 vol. %, from at least 3.0 vol. % to at most 7.0 vol. %, from at least 5.0 vol. % to at most 10.0 vol. %, from at least 10.0 vol. % to at most 20.0 vol. %, from at least 20.0 vol. % to at most 50.0 vol. %, or from at least 50.0 vol. % to at most 99.9 vol. % GeH₄ in H₂.

In some embodiments, the boron precursor is diborane, and the diborane is provided to the reactor chamber together with H₂ as a carrier gas. In some embodiments, a mixture of 0.1 vol. % to 10.0 vol. %, or 0.2 vol. % to 5.0 vol. %, or 0.4 vol. % to 2.5 vol. %, or 0.6 vol. % to 1.5 vol. %, or 0.8 vol. % to 1.2 vol. % diborane in H₂ may be used.

In some embodiments, the gallium precursor may be provided in a diluted form with a carrier gas.

Exemplary methods allow for selective growth-type doped silicon germanium layers within a pre-determined selectivity window. In other words, the present methods may be used to selectively grow boron and gallium doped silicon germanium on one part of a substrate (e.g., a monocrystalline silicon surface), whereas no, or no substantial amount of, growth occurs on another part of that substrate (e.g., a silicon oxide or nitride surface). A selectivity window is a thickness range of a grown layer in which the layer can be grown solely, or substantially solely, on one part of a substrate and not on one or more other parts of the substrate. Exemplary selectivity windows are 20 nm, 10 nm, 8 nm, 6 nm, 5 nm, 4 nm, 3 nm, 2 nm, and 1 nm.

As noted above, a substrate as used herein can include a first surface and a second surface. The first surface can be a monocrystalline surface, e.g., a monocrystalline silicon surface or a monocrystalline silicon germanium surface. Additionally or alternatively, the first surface may comprise a boron doped silicon germanium surface. Additionally or alternatively, the first surface may comprise a boron and gallium doped silicon germanium surface. The first surface preferably has a hydrogen termination. The first surface may be a surface of a doped layer, e.g., a boron-doped silicon layer. Alternatively, the first surface may be a surface of an undoped layer.

In some embodiments, the second surface is selected from the list consisting of a silicon oxide surface, a silicon nitride surface, a silicon oxycarbide surface, a silicon oxynitride surface, a hafnium oxide surface, a zirconium oxide surface, and an aluminum oxide surface. In some embodiments, material exposed on the second surface can include, for example, a dielectric material, such as an oxide, a nitride, an oxynitride, an oxycarbide, an oxycarbide nitride, and/or the like, such as silicon nitride, silicon oxide (SiO₂), silicon carbide and mixtures thereof, such as SiOC, SiOCN, SiON. In some embodiments, the second area has a silicon oxide surface. In other words, in some embodiments, the second material consists of silicon oxide (SiO₂).

When it is desirable to selectively grow a p-type doped silicon germanium layer having a thickness that is higher than the selectivity window, a cap-and-etch approach may be used. This may be done, for example, by introducing one or more cap layer precursors into the reactor chamber, thereby forming an epitaxial cap layer overlying the p-type doped silicon germanium layer, and then introducing an etch gas into the reactor chamber, thereby etching the epitaxial cap layer. Suitable etch gases include halogen-containing compounds. Exemplary halogens include fluorine, chlorine, bromine, and iodine. In some embodiments, the etch gas comprises chlorine. Exemplary chlorine-containing etch gases include HCl and Cl₂. An exemplary bromine-containing etch gas includes HBr. A suitable cap-and-etch approach is described, for example, in U.S. Provisional Application No. 62/930,752, which is hereby incorporated by reference in its entirety.

In some embodiments, the step of forming the p-type doped silicon germanium layer and the cap layer deposition step are separated by a purge step. The aforementioned cap-and-etch approach may be repeated in order to epitaxially grow layers of any desired thickness. In other words, in some embodiments, the sequence of the deposition step, capping step, and etching step are repeated as desired until a pre-determined thickness of the p-type doped silicon germanium layer is formed overlaying the first area. For example, the deposition step and the etching step can be repeated from at least 1 to at most 1000 times, from at least 2 to at most 100 times, from at least 2 to at most 50 times, from at least 2 to at most 30 times, from at least 2 to at most 20 times, from at least 5 to at most 15 times, or from at least 8 to at most 12 times.

In some embodiments, the one or more cap layer precursors comprise a silicon precursor and a boron precursor, and the cap layer comprises silicon and boron. For example, the silicon precursors and boron precursors mentioned above in the context of the p-type doped silicon germanium layer growth may be used as the silicon and boron precursors for the cap layer.

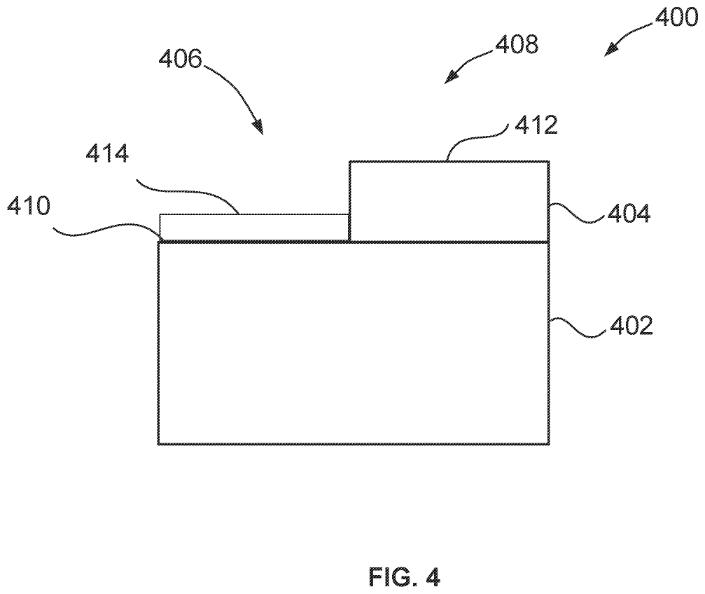

FIG. 4 illustrates a structure 400 in accordance with further examples of the disclosure. Structure 400 includes a first area 406 comprising a first material 402 (e.g., (mono)-crystalline bulk material) and a second area 408 comprising a second material 404 (e.g., non-monocrystalline material). First material 402 can include a first surface 410; second area 408 can include a second surface 412, such as a polycrystalline surface or an amorphous surface. First surface 410 can include a first surface as described above. Second surface 412 can include a second surface as described herein. As illustrated, a p-type doped silicon germanium layer 414 can be selectively formed on first surface 410. In accordance with further examples of the disclosure, p-type doped silicon germanium layer 414 form at least part of a source or drain region of a device.

In some cases, p-type doped silicon germanium layer 414 comprises zero or greater than 0 at % and not more than 2 at % or greater than 0.1 at % and not more than 1.5 at % indium. In some cases, P-type doped silicon germanium layer 414 comprises zero or greater than 0 at % and not more than 2 at % or greater than 0.2 at % and not more than 1.5 at % gallium. In some cases, P-type doped silicon germanium layer 414 comprises at least 0.1 at % and not more than 2 at % or greater than 0.2 at % and not more than 1.5 at % silicon. In some cases, P-type doped silicon germanium layer 414 comprises at least 30 at % and not more than 80 at % or greater than 40 at % and not more than 70 at % germanium.

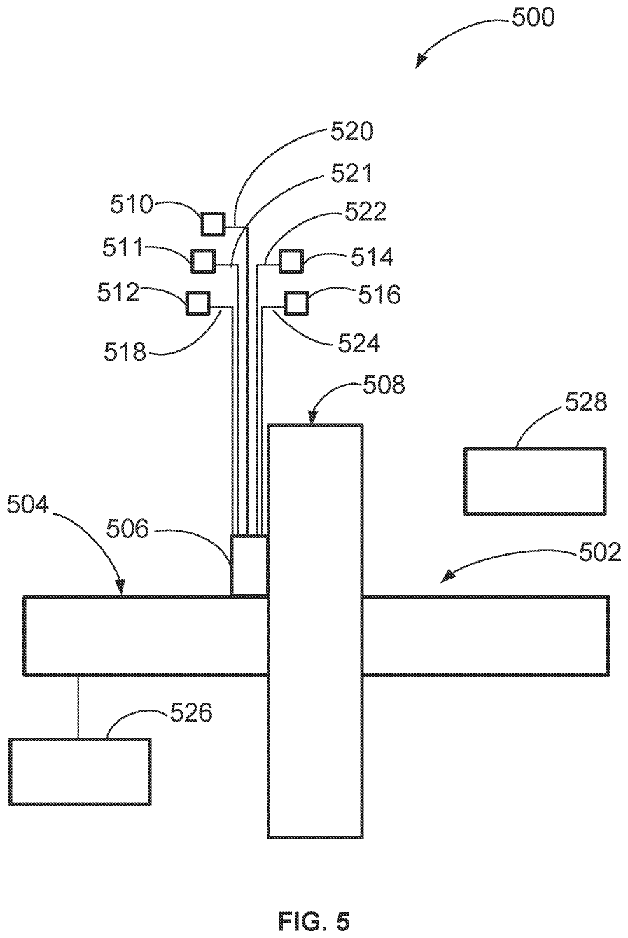

FIG. 5 illustrates a system 500 in accordance with yet additional exemplary embodiments of the disclosure. System 500 can be used to perform a method as described herein and/or form a structure or device portion as described herein.

In the illustrated example, system 500 includes an optional substrate handling system 502, one or more reaction chambers 504, a gas injection system 506, and optionally a wall 508 disposed between reaction chamber(s) 504 and substrate handling system 502. System 500 can also include a first gas source 510, a second gas source 512, a third gas source 514, a fourth gas source 516, a fifth gas source 511, an exhaust 526, and a controller 528. Each precursor source 510-516 can include a vessel and a precursor (e.g., silicon, germanium, and one or more p-type dopant precursors) as described herein.

Although illustrated with five gas sources 510-516, system 500 can include any suitable number of gas sources. In some cases, one of gas sources 510-516 or another gas source can include an etchant, such as an etchant noted herein. Gas sources 510-516 can be coupled to reaction chamber 504 via lines 518-524, which can each include flow controllers, valves, heaters, and the like.

System 500 can include any suitable number of reaction chambers 504 and substrate handling systems 502. Further, one or more reaction chambers 504 can be or include a cross-flow, cold wall epitaxial reaction chamber.

Exhaust source 526 can include one or more vacuum pumps.

Controller 528 can be configured to perform various functions and/or steps as described herein. For example, controller 528 can be configured for causing system 500 to perform any of methods 100-300.

Controller 528 can include one or more microprocessors, memory elements, and/or switching elements to perform the various functions. Although illustrated as a single unit, controller 528 can alternatively comprise multiple devices. By way of examples, controller 528 can be used to control gas flow (e.g., by monitoring flow rates of precursors and/or other gases from the gas sources 510-516 and/or controlling valves, motors, heaters, and the like). Further, when system 500 includes two or more reaction chambers, the two or more reaction chambers can be coupled to the same/shared controller.

During operation of reactor system 500, substrates, such as semiconductor wafers (not illustrated), are transferred from, e.g., a substrate handling system 502, to a reaction chamber 504. Once substrate(s) are transferred to the reaction chamber 504, one or more gases from gas sources 510-516, such as precursors, dopants, carrier gases, and/or purge gases, are introduced into the reaction chamber 504 via a gas injection system 506. Gas injection system 506 can be used to meter and control gas flow of one or more gases (e.g., from one or more gas sources 510-516) during substrate processing and to provide desired flows of such gas(es) to multiple sites within the reaction chamber 504.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

What is claimed is:

1. A method of forming a p-type doped silicon germanium layer, the method comprising the steps of:
providing a substrate within a reaction chamber of a reactor; and
forming the p-type doped silicon germanium layer, the step of forming comprising:
providing a silicon precursor to the reaction chamber;
providing a germanium precursor to the reaction chamber; and
providing one or more p-type dopant precursors to the reaction chamber,
wherein the one or more p-type dopant precursors comprise boron, gallium and indium.

2. The method according to claim 1, wherein the p-type doped silicon germanium layer is epitaxially formed on the substrate.

3. The method according to claim 1, wherein a temperature during the step of forming the p-type doped silicon germanium layer is less than 800° C. or between about 300° C. and about 800° C. or between about 350° C. and about 500° C.

4. The method according to claim 1, wherein the one or more p-type dopant precursors comprise one or more of a borane having a formula BₓH_{y} where x is between 1-12 and where y≥x and y≤3x, deuterium-diborane (B₂D₆), or one or more borohydride compounds.

5. The method according to claim 4, wherein the one or more borohydride compounds comprise a borohydride represented by the formula YₓM(BH₄)₃₋ₓ, wherein Y is independently chosen from hydrogen, deuterium, chlorine, bromine, and iodine; M is a Group 13 metal independently chosen from gallium and indium; and x is an integer from 0-2.

6. The method according to claim 4, wherein the one or more borohydride compounds are selected from the group consisting of gallium borohydride (Ga(BH₄)₃) and indium borohydride (In(BH₄)₃).

7. The method according to claim 4, wherein the one or more borohydride compounds comprise a borohydride represented by the formula RₓM(BH₄)₃₋ₓ, wherein R is independently chosen from CH₃, C₂H₅, C₆H₅, CF₃SO₃, and NH₂; M is a Group 13 metal independently chosen from gallium and indium; and x is an integer from 1 to 3.

8. The method according to claim 1, wherein the one or more p-type dopant precursors comprise one or more of an indium organometallic compound and an indium halide compound.

9. The method according to claim 1, wherein the one or more p-type dopant precursors comprise one or more of an indium alkyl compound and an indium alkyl-amino compound.

10. The method according to claim 1, wherein the one or more p-type dopant precursors comprise one or more of trimethylindium, triethylindium, dimethylaminopropyl-dimethyl-indium, indium trichloride, and indium compounds comprising one or more adducts selected from the group BH₃—NR₃, BH₃—SR₂, and B(NR₂)₃, wherein each R can be independently selected from hydrogen, methyl, ethyl, 1-propyl, 2-propyl, cyclopropyl, 1-butyl, 2-butyl, 2-methylpropyl, tert-butyl, cyclobutyl, 1-pentyl, 1,1-dimethylpropyl, 2,2-dimethylpropyl, 3-methylbutyl, 1-methylbutyl, 1-ethylpropyl, 1,2-dimethylpropyl, 2-methylbutyl, cyclopentyl, 1-hexyl, 2-hexyl, 3-hexyl, 1-methyl-1-ethylpropyl, 1,1-dimethylbutyl, cyclohexyl, phenyl, benzyl, trimethylsilyl, and triethylsilyl functional groups.

11. The method according to claim 1, wherein a concentration of indium in the p-type doped silicon germanium layer is greater than 0 at % and not more than 2 at % or greater than 0.1 at % and not more than 1.5 at %.

12. A method of forming a p-type doped silicon germanium layer, the method comprising the steps of:
providing a substrate within a reaction chamber of a reactor; and
forming the p-type doped silicon germanium layer comprising boron and gallium, the step of forming comprising:
providing a silicon precursor to the reaction chamber;
providing a germanium precursor to the reaction chamber; and
providing one or more p-type dopant precursors to the reaction chamber,
wherein the one or more p-type dopant precursors comprise one or more of gallium tribromide or gallium triiodide.

13. The method according to claim 12, wherein the silicon precursor comprises one or more of a silane, an alkylsilane, a halogen-substituted silane, or a silicon precursor including two or more silicon atoms.

14. The method according to claim 12, wherein one or more p-type dopant precursors further comprises a boron precursor.

15. The method according to claim 14, wherein the boron precursor comprises one or more of a borane, deuterium-diborane (B₂D₆), or one or more borohydrides.

16. The method of claim 12, wherein the one or more p-type dopant precursors further comprises an indium precursor.

17. The method of claim 12, wherein a temperature of the substrate is less than 450° C., less than 400° C., or between about 300° C. and about 400° C. or between about 320° C. and about 380° C.

18. A method of forming a p-type doped silicon germanium layer, the method comprising the steps of:
providing a substrate within a reaction chamber of a reactor; and
forming the p-type doped silicon germanium layer, the step of forming comprising:
providing a silicon precursor to the reaction chamber;
providing a germanium precursor to the reaction chamber; and
providing one or more p-type dopant precursors to the reaction chamber,
wherein the silicon precursor comprises one or more of bromine and iodine.

19. The method according to claim 18, wherein the silicon precursor is represented by the formula SiXₐH₄₋ₐ, wherein each X is an independently selected halogen selected from the group consisting of I and Br; and a is at least 1 and not more than ₄ or the formula SiₐX2ₐ₊₂₋ₙHₙ, where a is from 2 to 5 or the formula SiₐX2ₐ₋ₙHₙ, where a is 3-6.

20. The method according to claim 18, wherein the p-type doped silicon germanium layer comprises boron and gallium.

21. The method of claim 12, wherein a temperature of the substrate is less than 450° C., less than 400° C., or between about 300° C. and about 400° C. or between about 320° C. and about 380° C.

22. The method of claim 12, wherein the p-type doped silicon germanium layer is selectively formed overlying a first surface of the substrate, relative to a second surface of the substrate.

23. The method of claim 22, wherein an etchant is not used during the step of forming the p-type doped silicon germanium layer.

24. A method of forming one or more of a source region and a drain region of a device using the method of claim 1.

25. A structure comprising:
one or more of a source and a drain region formed according to the method of claim 1.
